(19) United States
(12) Patent Application Publication
(10) Pub. No.: US 2008/0272452 A1
(43) Pub. Date: Nov. 6, 2008

(54) IMAGE SENSOR AND METHOD FOR MANUFACTURING THE SAME

(76) Inventor: Jong-Taek Hwang, Cheongju-si (KR)

Correspondence Address: SHERR & VAUGHN, PLLC, 620 HERNDON PARKWAY, SUITE 200, HERNDON, VA, 20170, US

(21) Appl. No.: 12/111,221

(22) Filed: Apr. 29, 2008

(30) Foreign Application Priority Data
May 3, 2007 (KR) 10-2007-0042910

(51) Int. Cl. H01L 31/0232; H01L 31/18

(52) U.S. Cl. 257/432; 438/70; 257/E31.127

(57) ABSTRACT

An image sensor that includes a hard mask layer formed in the upper surface region of the planarization layer and under a microlens to protect an underlying planarization layer from chemicals used during performing a cleaning process after formation of the microlens. The microlens is composed of inorganic materials to prevent cracking by physical impacts.

The present application claims priority under 35 U.S.C. 119 and 35 U.S.C. 365 to Korean Patent Application No. 10-2007-0042910 (filed on May 3, 2007), which is hereby incorporated by reference in its entirety.

### BACKGROUND

Image sensors are semiconductor devices for converting an optical image into an electrical signal. Image sensors may be classified as a charge coupled device (CCD) image sensor and a complementary metal oxide silicon (CMOS) image sensor (CIS).

A CMOS image sensor may include a photodiode and a MOS transistor within a unit pixel for sequentially detecting electrical signals of each unit pixel in a switching manner, thereby implementing an image.

In a manufacturing process of a CMOS image sensor, processes may include forming a microlens on and/or over a color filter, which is formed on and/or over a pixel array substrate formed with a pixel. The microlens may be formed using a condensing technique for enhancing light sensitivity. The microlens may be formed in a hemisphere shape by sequentially exposing, developing, and reflowing photosensitive organic materials.

Photosensitive organic materials, however, are weak in their properties, and thus, the microlens may be easily damaged due to cracks, etc. by physical impacts during subsequent processes such as a package and a bump, etc.

### SUMMARY

Embodiments relate to an image sensor and a method for manufacturing thereof, having a microlens made of inorganic materials.

Embodiments relate to an image sensor that can include at least one of the following: a metal wire layer formed on a semiconductor substrate; a color filter layer formed on the metal wiring layer; a planarization layer formed on the color filter; a hard mask layer formed in the upper surface region of the planarization layer; and a microlens formed on the hard mask layer.

Embodiments relate to method for manufacturing an image sensor that can include at least one of the following steps: forming a metal wiring layer on a semiconductor substrate; and then forming a color filter layer on the metal wiring layer; and then forming a planarization layer on the color filter layer; and then forming a hard mask layer in an upper region of the planarization layer; and then forming a microlens on the hard mask layer.

Embodiments relate to method for manufacturing an image sensor that can include at least one of the following steps: forming an interlayer dielectric layer lay including a plurality of metal wires on a semiconductor substrate; and then forming a color filter layer on the metal wiring layer; and then forming a planarization layer on the color filter layer; and then forming a chemically resistant hard mask layer in an upper region of the planarization layer; and then forming a microlens on the hard mask layer.

### DRAWINGS

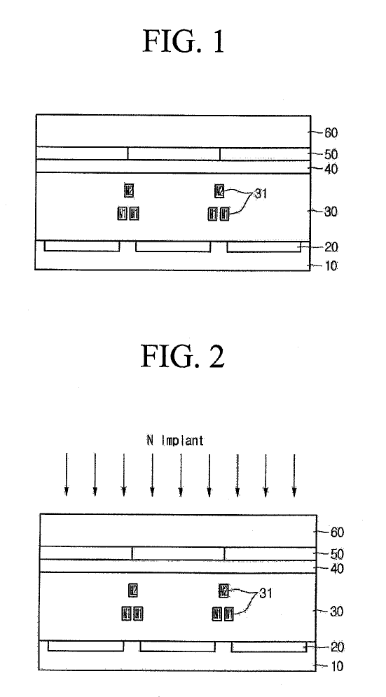

Example FIGS. 1 to 6 illustrate manufacturing processes of an image sensor, in accordance with embodiments.

### DESCRIPTION

As illustrated in example FIGS. 1-6, in accordance with embodiments, an image sensor can include a metal wiring layer formed on and/or over semiconductor substrate 10 including a unit pixel. A plurality of photo sensors 20 may be formed in semiconductor substrate 10. The metal wiring layer can include an interlayer dielectric films 30 having a plurality of metal wirings 31 formed in interlayer dielectric film 30. In order to protect the device, passivation layer 40 may be formed on and/or over the upper surface of the metal wiring layer. Color filter layer 50 can be formed on and/or over interlayer dielectric films 30 (or on and/or passivation layer 40). Planarization layer 60 can be formed on and/or over color filter layer 50 and hard mask layer 65 can be formed on and/or over planarization layer 60. Hard mask layer 65 can be formed by implanting nitrogen ions into an upper surface of planarization layer 60. Hard mask layer 65 can thus, protect the planarization layer 60. The microlens 75 is formed of a low temperature oxide film, making it possible to prevent cracks, etc., by physical impacts. Microlens 75 can be formed on and/or over hard mask layer 65.

As illustrated by example FIG. 1, a plurality of photo sensors 20 including a photodiode and a CMOS circuit can be formed on and/or over semiconductor substrate 10. A device isolation film defining an active region and a filed region can be formed in semiconductor substrate 10. Each unit pixel can be formed with a photodiode for receiving light and generating a photocharge and a transistor connected to the photodiode converting the received photocharge into an electrical signal.

After relevant devices including the device isolation film and photo sensors 20 are formed, a metal wiring layer can then be formed on and/or over semiconductor substrate 10. The metal wiring layer can include interlayer dielectric film 30 formed on and/or over semiconductor substrate 10 and a plurality of metal wirings 31 formed by penetrating through interlayer dielectric film 30. Interlayer dielectric film 30 including metal wirings 31 can have a multi-layer structure including a plurality of layers. Metal wires 31 can be formed to be intentionally laid-out so as not to shade light incident on the photodiodes. A pad can be formed above the metal wirings 31.

Passivation layer 40 can then be formed on and/or over interlayer dielectric layer 60 including metal wirings 31 to protect a device from moisture and scratching, etc. Passivation layer 40 may be formed having a multi-layered structure and composed of at least one of a silicon oxide film, a silicon nitride film and a silicon oxynitride film.

Color filter layer 50 including a plurality of color filters can be formed directly on and/or over passivation layer 40. Alternatively, color filter layer 50 can then be formed directly on and/or over interlayer dielectric layer 30. This structure reduces the overall thickness of the image sensor, making it possible to manufacture a thinner image sensor at a reduced overall cost. Color filter layer 50 can be formed having a plurality of colors, such as three colors for implementing a color image. Color filter layer 50 can be composed of a dyed photoresists such that each color filter is formed corresponding to a respective unit pixel to classify colors from the light incident. Such a color filter that represents each different color such as red, green and blue. Adjacent color filters in color filter layer 50 can be somewhat overlapped with each other to produce a step differential.

In order to overcome the step differential on color filter layer 50, planarization layer 60 can be formed on and/or over color filter layer 50. Accordingly, a microlens to be formed by a subsequent process can be formed on and/or over a planarized surface. Planarization layer 60 can be formed by coating the upper surface of semiconductor substrate 10 formed with color filter layer 50 with planarization materials. For example, planarization layer 60 can be formed of an organic material having a thickness of between 4,000 to 8,000 Å. Planarization layer 60 can be an overcoating layer that is a photoresist.

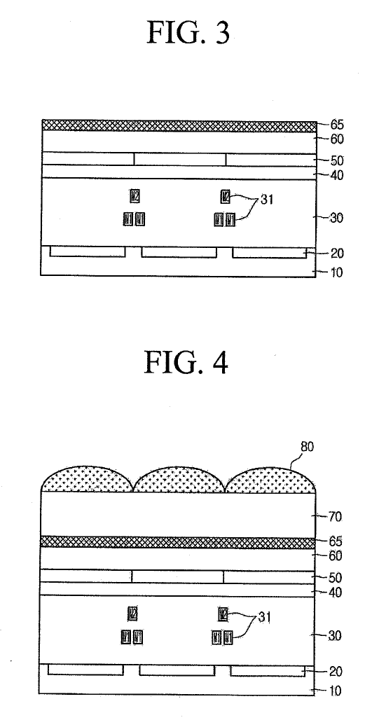

As illustrated in example FIGS. 2 and 3, a plurality of nitrogen ions can then be implanted into an upper surface region of planarization layer 60 through an ion implant process to from hard mask layer 65. For example, the nitrogen ions can be implanted using energy of between 20 to 250 KeV and a dosage of between 2×10¹³ to 2×10¹⁴ atoms/cm2 to form hard mask layer 65 in an upper surface region of planarization layer 60. Meaning, as the nitrogen ions are implanted into the upper surface region of planarization layer 60, hard mask layer 65 can be formed therein. Hard mask layer 65 can be formed having a thickness of between 10 to 500 Å. The surface of hard mask layer 65 is formed hard due to the nitrogen ions which is chemically resistant, and thus, cannot be dissolved by chemicals. Therefore, planarization layer 60 and color filter layer 60, which are formed of organic materials, can be protected by hard mask layer 65.

As illustrated in example FIG. 4, inorganic layer 70 can then be formed on and/or over hard mask layer 65. Inorganic layer 70 can be formed of inorganic materials such as at least one of an oxide film, a nitride film and an oxynitride film. For example, inorganic layer 70 can be formed through a CVD process, a PVD process, and a PEDVD process, at a low temperature of about 50 to 250° C. and having a thickness of between 2,000 to 20,000 Å. Microlens patterns 80 can then be formed on and/or over inorganic layer 70. Microlens patterns 80 can be formed in a semispherical or dome shape by applying an organic photoresist film on and/or over inorganic layer 70 and performing exposure, development, and reflow processes.

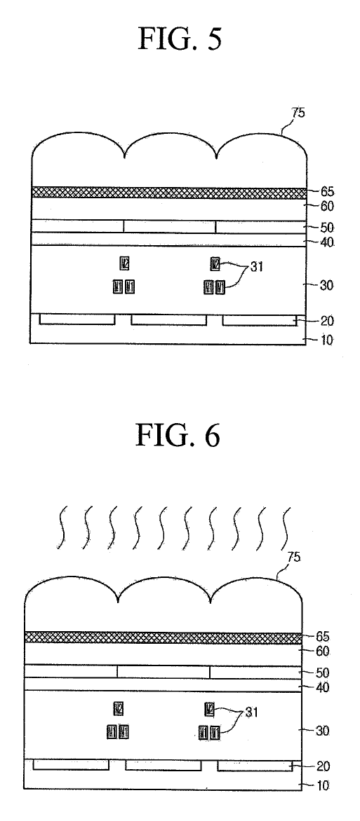

As illustrated in example FIG. 5, microlens array 75 composed of a plurality of microlenses can then be formed on and/or over hard mask 65 by etching inorganic layer 70 using microlens pattern 80 as an etching mask. The entire etching of inorganic layer 70 can be performed at a 1:1 etching selection ratio between inorganic layer 70 and microlens pattern 80. The etching selection ratio is not limited thereto, however, inorganic layer 80 can be over-etched by controlling the etching selection ratio. Therefore, the etching of inorganic layer 70 when forming microlens 75 can be performed until the organic photoresist film is completely etched so that microlens 75 can be formed in a continuous shape, i.e., without gaps between adjacent or neighboring microlens. Microlens 75 can be formed of a low temperature oxide film. If microlens 75 is formed having a plurality microlenses spaced apart from each other, a double-layer structure can be formed by cleaning and then depositing a thin inorganic thin film on and/or over microlens 75.

As illustrated in example FIG. 6, a surface cleaning process on microlens 75 can then be performed to remove particles such as organic photoresist residue, etc., remaining on microlens 75 during formation of microlens 75. Such photoresist residue may act as an image defect source by causing a black spot on the image sensor. The surface cleaning process may be formed using a chemical such as H₂SO₄, HF and HNO₃ on microlens 75.

Because microlens 75 can be formed of a low temperature oxide film, the quality of the oxide film can be loosely formed so that pin holes can exist therein. When performing a cleaning process on microlens 75, the cleaning chemical can penetrate into a lower layer of microlens 75 through the pin holes, and thus, into planarization layer 60 and/or color filter layer 50. This can dissolve the organically composed color filter layer 50. Therefore, the organic layer is detached from microlens 75, thereby causing a defect in the image sensor.

However, in accordance with embodiments, hard mask layer 65 is formed under microlens 75 to protect planarization layer 60 from the chemicals used during performing a cleaning process. Accordingly, it is possible to prevent the dissolution of planarization layer 60. Therefore, although cleaning chemicals may penetrate into microlens 75 through pin holes, the dissolution of planarization layer 60 composed of organic materials can be prevented through hard mask layer 65. The quality of the image sensor is enhanced.

Moreover, after forming microlens 75, the surface cleaning process thereon is performed, making it possible to prevent a defect of the image sensor.

Because microlens 75 is composed of inorganic materials, it is possible to prevent cracks, etc., by physical impacts.

With the image sensor and the method for manufacturing the same, the microlens made of inorganic materials is used to prevent damages such as particles and cracks, making it possible to improve quality of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a metal wire layer formed on a semiconductor substrate;
a color filter layer formed on the metal wiring layer;
a planarization layer formed on the color filter;
a hard mask layer formed in the upper surface region of the planarization layer; and
a microlens formed on the hard mask layer.

2. The image sensor of claim 1, wherein the hard mask layer comprises an organic film implanted with nitrogen ions.

3. The image sensor of claim 1, wherein the hard mask layer has a thickness of between 10 to 500 Å.

4. The image sensor of claim 1, wherein the microlens comprises a low temperature oxide film.

5. The image sensor of claim 1, further comprising a passivation layer formed on the metal wiring layer and under the color filter layer.

6. A method for manufacturing an image sensor comprising:
forming a metal wiring layer on a semiconductor substrate; and then
forming a color filter layer on the metal wiring layer; and then
forming a planarization layer on the color filter layer; and then
forming a hard mask layer in an upper region of the planarization layer; and then forming a microlens on the hard mask layer.

7. The method of claim 6, wherein forming the hard mask layer comprises:
forming an inorganic layer as the planarization layer on the color filter; and then applying nitrogen to the upper region of the planarization layer.

8. The method of claim 7, wherein applying nitrogen comprises implanting nitrogen ions into the upper region of the planarization layer by an ion implantation method.

9. The method of claim 8, wherein the ion implantation method is performed using energy of between 20 to 250 KeV and a dosage of between 2×10¹³ to 2×10¹⁴ atoms/cm2.

10. The method of claim 6, wherein the microlens comprises a low temperature oxide film.

11. The method of claim 6, wherein forming the microlens comprises:
forming an inorganic layer on the hard mask layer; and then
forming a plurality of microlens patterns on the inorganic layer; and then
etching the inorganic layer using the microlens patterns as etching masks.

12. The method of claim 6, further comprising performing a cleaning process on the microlens after forming the microlens.

13. The method of claim 12, wherein the cleaning process is performed using at least one of H₂SO₄, HF and HNO₃.

14. A method comprising:
forming an interlayer dielectric layer lay including a plurality of metal wires on a semiconductor substrate; and then
forming a color filter layer on the metal wiring layer; and then
forming a planarization layer on the color filter layer; and then
forming a chemically resistant hard mask layer in an upper region of the planarization layer; and then
forming a microlens on the hard mask layer.

15. The method of claim 14, wherein forming the hard mask layer comprises:
forming a planarization layer on the color filter; and then
implanting nitrogen ions into the upper region of the planarization layer.

16. The method of claim 14, wherein implanting nitrogen ions is performed using energy of between 20 to 250 KeV and a dosage of between 2×10¹³ to 2×10¹⁴ atoms/cm2.

17. The method of claim 14, wherein forming the microlens array comprises:
forming an inorganic layer on the hard mask layer; and then
forming a plurality of microlens patterns on the inorganic layer; and then
etching the inorganic layer using the microlens patterns as etching masks.

18. The method of claim 17, wherein the inorganic layer comprises at least one of an oxide film, a nitride film and an oxynitride film.

19. The method of claim 17, wherein the inorganic layer is formed at a temperature of about 50 to 250° C.

20. The method of claim 17, wherein the inorganic layer has a thickness of between 2,000 to 20,000 Å.
